(19) United States
(12) Patent Application Publication
(10) Pub. No.: US 2013/0228799 A1
(43) Pub. Date: Sep. 5, 2013

(54) METHOD FOR PRODUCING A SILICONE FOIL, SILICONE FOIL AND OPTOELECTRONIC SEMICONDUCTOR COMPONENT COMPRISING A SILICONE FOIL

(71) Applicants: Stephan Preuss, Bad Abbach (DE); Tobias Geltl, Pfoerring (DE); Thomas Schiller, Lehen-Bernhardswald (DE); Hans-Christoph Gallmeier, Regensburg (DE)

(72) Inventors: Stephan Preuss, Bad Abbach (DE); Tobias Geltl, Pfoerring (DE); Thomas Schiller, Lehen-Bernhardswald (DE); Hans-Christoph Gallmeier, Regensburg (DE)

(73) Assignee: Osram Opto Semiconductors GmbH, Regensburg (DE)

(21) Appl. No.: 13/877,270

(22) PCT Filed: Aug. 17, 2011
(86) PCT No.: PCT/EP11/64174

§ 371 Date: May 15, 2013

(30) Foreign Application Priority Data
Oct. 4, 2010 (DE) 10 2010 047454.1

(51) Int. Cl. B29C 67/24; H01L 33/48

(52) U.S. Cl. CPC B29C 67/24; H01L 33/48
USPC 257/79; 428/141; 428/143; 264/138; 264/160

(57) ABSTRACT

A method of producing a silicone foil for use in an optoelectronic semiconductor component by molding including introducing a mold foil into a mold, introducing a carrier foil into the mold, wherein the carrier foil is fitted on a substrate foil and the substrate foil projects laterally beyond the carrier foil at least in places within a cavity of the mold, providing and applying a silicone base composition to the mold foil or to the carrier foil, molding the silicone base composition for the silicone foil in the mold between the mold foil and the carrier foil, wherein the silicone base composition is brought into contact with the substrate foil in at least one overlap region laterally alongside the carrier foil, removing the mold foil from the silicone foil, and separating the overlap region.

### TECHNICAL FIELD

This disclosure relates to a method of producing a silicone foil, particularly to a silicone foil and an optoelectronic semiconductor component comprising such a silicone foil.

### BACKGROUND

There is a need to provide a method of producing a silicone foil, wherein the silicone foil can be produced by molding and is suitable for use in an optoelectronic semiconductor component.

### SUMMARY

We provide a method of producing a silicone foil for use in an optoelectronic semiconductor component by molding including introducing a mold foil into a mold, introducing a carrier foil into the mold, wherein the carrier foil is fitted on a substrate foil and the substrate foil projects laterally beyond the carrier foil at least in places within a cavity of the mold, providing and applying a silicone base composition to the mold foil or to the carrier foil, molding the silicone base composition for the silicone foil in the mold between the mold foil and the carrier foil, wherein the silicone base composition is brought into contact with the substrate foil in at least one overlap region laterally alongside the carrier foil, removing the mold foil from the silicone foil, and separating the overlap region.

We also provide a silicone foil including a matrix material including a silicone, conversion particles distributed substantially homogeneously in the matrix material, two mutually opposite main sides, and a grooved roughening formed at at least one of the main sides, wherein an average thickness of the silicone foil is 20 μm to 250 μm.

We further provide an optoelectronic semiconductor component including at least one optoelectronic semiconductor chip, and at least one silicone lamina composed of the silicone foil including a matrix material including a silicone, conversion particles distributed substantially homogeneously in the matrix material, two mutually opposite main sides, and a grooved roughening formed at at least one of the main sides, wherein an average thickness of the silicone foil is 20 μm to 250 μm, wherein the silicone lamina is fitted at least indirectly at a radiation main side of the semiconductor chip and at least partly covers the radiation main side.

### BRIEF DESCRIPTION OF THE DRAWINGS

FIG. 1 shows a schematic illustration of a method described of producing a silicone foil.

FIG. 2 shows schematic side views of examples of optoelectronic semiconductor components including silicone foils.

FIGS. 3 and 4 show schematic illustrations of examples of silicone foils.

### DETAILED DESCRIPTION

Our method may comprise the steps of introducing a mold foil and introducing a carrier foil into a mold. In this case, the mold foil is designed to fill a cavity of the mold in a positively locking manner at least in places. The mold foil is, in particular, a mold release foil. The mold foil can therefore imitate a shape of a part of the cavity and/or of a cavity-defining mold half of the mold. During molding, the mold foil can preferably also reproduce a shape of the cavity which changes as a result of the molding process.

The carrier foil is a foil which differs from the mold foil and which is preferably not or not significantly deformed during molding. The carrier foil carries the silicone foil produced by the method after molding. By way of example, the carrier foil is formed in a flat and planar fashion in the mold. The carrier foil preferably bears at least indirectly against a flat mold half of the mold. The carrier foil in particular does not copy the cavity.

The carrier foil may be fitted on a substrate foil. The substrate foil preferably comprises a material that differs from the carrier foil and is situated at a side of the carrier foil facing away from the cavity of the mold.

The carrier foil and also the substrate foil and the mold foil may be handled in a roll-to-roll process. The foils mentioned are therefore unrolled from one or more rolls and led into the mold. Afterward, at least one of the foils can be rolled up again onto other rolls. It is possible for all foils in the mold to be completely or partly exchanged between two successive molding processes.

The substrate foil may project beyond the carrier foil in a lateral direction at least in places within the cavity of the mold. Preferably, the substrate foil projects beyond the carrier foil in a ring-shaped or frame-shaped manner such that the substrate foil projects laterally beyond the carrier foil completely all around. Laterally means, in particular, along main extension directions of the silicone foil to be produced by the method. In other words, the carrier foil, as seen in plan view, is bordered in places or completely by the substrate foil, in particular with a uniform width.

The method may comprise the step of providing and applying a silicone base composition to the mold foil and/or to the carrier foil. The silicone base composition is, for example, at least one polysilane, siloxane and/or polysiloxane. The silicone base composition constitutes a starting material for the silicone foil. During application, the silicone base composition is present such that it is not completely cured and/or not completely crosslinked.

The method may comprise the step of molding the silicone base composition into the shape of the silicone foil in the mold. In this case, the silicone foil is formed between the mold foil and the carrier foil. In this case, the silicone base composition and the silicone foil are preferably in direct physical contact both with the mold foil and the carrier foil. Direct contact with the mold is preferably not present. Furthermore, the silicone base composition and/or the silicone foil are/is in direct contact with the substrate foil in an overlap region laterally alongside the carrier foil. Molding to form the silicone foil is effected by closing the mold. The molding is preferably compression molding.

The method may comprise the step of removing the mold foil from the silicone foil. The mold foil is removed after the mold has been opened. During removal of the mold foil, the silicone foil is partly or completely cured. After removal of the mold foil, the silicone foil is still in direct contact with the carrier foil and, laterally alongside the carrier foil, with the substrate foil.

The method may comprise the step of separating the overlap region. By way of example, the overlap region is cut off or stamped off. After the overlap region has been separated the silicone foil is preferably only in direct physical contact with the carrier foil and no longer with the substrate foil or the mold foil.

The method may produce a silicone foil for use in an optoelectronic semiconductor component. The silicone foil is produced by molding, preferably compression molding. The method comprises at least the following steps:
introducing a mold foil into a mold,
introducing a carrier foil into the mold, wherein the carrier foil is fitted on a substrate foil and the substrate foil projects laterally beyond the carrier foil at least in places within a cavity of the mold,
providing and applying a silicone base composition to the mold foil or to the carrier foil,
molding the silicone base composition for the silicone foil in the mold between the mold foil and the carrier foil, wherein the silicone base composition is brought into contact with the substrate foil in at least one overlap region laterally alongside the carrier foil,
removing the mold foil from the silicone foil, and
separating the overlap region.

The individual method steps are preferably performed in the specified order. In a departure therefrom, individual method steps can also be performed in a different order.

Specific requirements are made of the mold foil in respect of, in particular, extensibility, tear strength, moldability and surface constitution. As a result, a choice of materials for the mold foil is greatly restricted. In particular, the silicone foil may have a comparatively strong adhesion to the mold foil after molding.

The substrate foil which adheres comparatively strongly to the silicone foil and projects laterally beyond the carrier foil ensures that, during removal of the mold foil, the silicone foil produced remains at the substrate foil and at the carrier foil. As a result of the subsequent removal of the overlap region of the silicone foil with the substrate foil, as seen in plan view, the silicone foil remains only at the carrier foil. The silicone foil can have a comparatively low adhesion to the carrier foil such that further processing of the silicone foil, in particular with subsequent rebonding steps, is simplified.

The silicone base composition and/or the silicone foil may adhere(s) more strongly to the substrate foil than to the mold foil. Furthermore, the silicone base composition and/or the silicone foil may adhere(s) more strongly to the mold foil than to the carrier foil. A measure of the adhesion capacity is, in particular, the static friction or the adhesive force per unit area.

A surface structure of the mold foil and/or of the carrier foil may be reproduced at the silicone foil during molding. In other words, the silicone foil takes over the surface structure of the mold foil and/or of the carrier foil at at least one main side. In particular, a roughening or grooves present in that side of the carrier foil facing the silicone foil is or are transferred into at least one of the main sides of the silicone foil.

The silicone foil may be precured with the mold closed. Complete curing of the silicone foil is effected only after the mold has been opened. Removal of the mold foil from the silicone foil can be effected before or after the complete curing of the silicone foil. This likewise applies to separation of the overlap region.

A conversion means may be admixed with the silicone composition prior to application to the carrier foil or to the mold foil. The conversion means is preferably present in the form of conversion means particles and is furthermore preferably admixed with the silicone base composition in a homogeneously distributed manner. The conversion means is designed to at least partly absorb electromagnetic radiation in a first wavelength range and convert it into a radiation in a second wavelength range, which differs from the first wavelength range. By way of example, the conversion means particles are designed to absorb radiation at a wavelength of 420 nm to 490 nm and convert it into a longer-wave radiation.

The viscosity of the silicone base composition during application to the carrier foil or to the mold foil may be comparatively high. Comparatively high can mean that the silicone base composition does not intrinsically run on the mold foil or on the carrier foil. In particular, the viscosity of the silicone base composition during application is at least 0.1 Pa·s or at least 1.0 Pa·s or at least 10 Pa·s or at least 20 Pa·s.

The silicone foil, in particular after removal from the mold and after separation of the overlap region, may be singulated to form a multiplicity of silicone laminae, also referred to as disk or plate. Singulation to form the silicone laminae is effected, for example, by cutting or stamping.

The thickness of the silicone foil in the mold, across the entire silicone foil, may fluctuate by at most 15% around an average thickness of the silicone foil. In other words, the silicone foil may have a uniform thickness. In particular, the fluctuation around the average thickness is at most 10% or at most 5%. This makes it possible to realize, for example, a very uniform conversion of radiation by silicone laminae produced from the silicone foil with conversion means particles.

Furthermore, a silicone foil is specified. The silicone foil is produced by a method as described in at least one of the examples mentioned above. Features for the silicone foil are therefore also disclosed for the method, and vice versa.

The silicone foil may comprise a matrix material comprising a silicone or consisting of a silicone. Conversion means particles are embedded in the matrix material in a homogeneously distributed manner. Homogeneously distributed means, in particular, that concentration fluctuations of the conversion means particles do not go beyond purely statistical deviations. Furthermore, the silicone foil has two mutually opposite main sides. A roughening is formed at one or at both main sides, wherein the roughening is configured in a grooved fashion at least at one of the main sides. In other words, the roughening comprises grooved structures or substantially consists thereof. Furthermore, an average thickness of the silicone foil is at least 20 μm and/or at most 250 μm, in particular at least 40 μm and/or at most 160 μm.

In the silicone foil, an average roughness depth of the roughening may be 0.05 μm to 15 μm, preferably 0.1 μm to 5 μm, or 0.1 μm to 1 μm.

In the silicone foil, the grooves of the roughening may have an average groove length of at least 50 μm or of at least 1 mm, in particular 50 μm to 150 mm or 1 mm to 100 mm. In this context, the term “groove” or “grooved” preferably also includes such structures shaped as the negative with respect to grooves, that is to say, for example, elongated, wall-shaped elevations at the main side of the silicone foil. The grooves and/or the elevations preferably extend along or substantially along a common main extension direction.

Moreover, we provide an optoelectronic semiconductor component. The semiconductor component comprises at least one optoelectronic semiconductor chip, preferably a light-emitting diode, LED for short, which emits a maximum intensity in particular at a wavelength of 420 nm to 490 nm. Furthermore, the semiconductor component comprises at least one silicone lamina composed of a silicone foil as described in at least one of the examples above. Features of the semiconductor component are therefore also disclosed for the silicone foil and the method of producing the silicone foil, and vice versa. The silicone lamina of the semiconductor component is fitted at least indirectly at a radiation main side of the semiconductor chip and partly or completely covers the radiation main side.

A silicone foil described here, an optoelectronic semiconductor component described here and a method described here are explained in greater detail below on the basis of examples with reference to the drawings. In this case, identical reference signs indicate identical elements in the individual figures. In this case, however, relations to scale are not illustrated. Rather, individual elements may be illustrated with an exaggerated size in order to afford a better understanding.

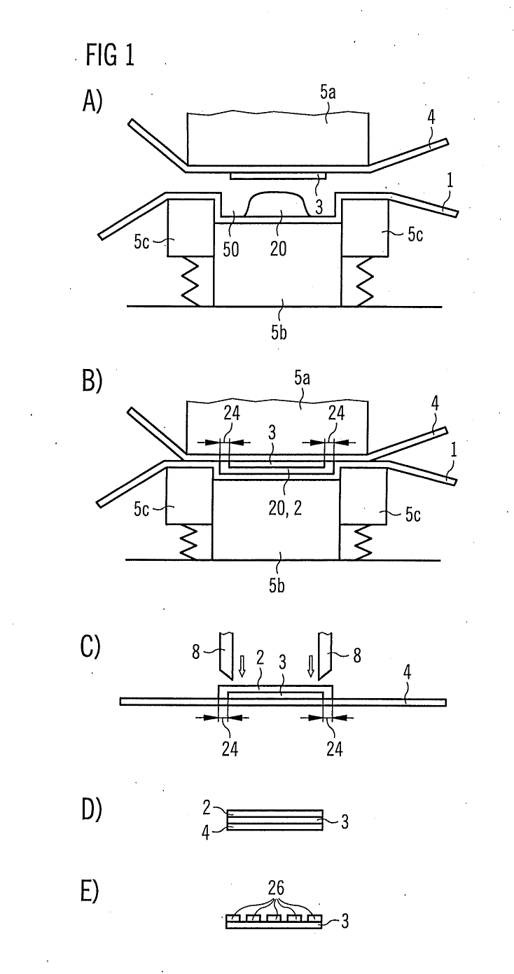

FIGS. 1A to 1E illustrate a method of producing a silicone foil 2 in schematic sectional illustrations. In accordance with FIG. 1A, a mold foil 1 and a carrier foil 3, which is fitted on a substrate foil 4, are introduced into a cavity 50 of a mold 5a, 5b, 5c. The carrier foil 3 and the substrate foil 4 bear in a planar manner on a flatly shaped main side of the part 5a of the mold. The mold foil 1 bears in a positively locking manner against the parts 5b, 5c of the mold. Within the cavity 50, the substrate foil 4 projects beyond the carrier foil 3 all around. The cavity 50 is configured in a circular fashion, for example, in plan view, perpendicular to the plane of the drawing of FIG. 1, and the carrier foil 3 is arranged, in particular, in a laterally centered manner in the cavity 50.

Furthermore, in accordance with FIG. 1A, a silicone base composition 20 for the silicone foil 2 is introduced into the cavity 50. By way of example, the silicone base composition 20 is applied to the mold foil 1 in the cavity 50. The silicone base composition 20 has a comparatively high viscosity during introduction into the cavity 50 and does not run or does not significantly run.

The mold foil 1 and the carrier foil 3 are preferably in each case polyfluorolefin foils. In this case, a degree of fluorination of the carrier foil 3 is preferably greater than in the case of the mold foil 1. In particular, the carrier foil 3 is a polytetrafluorethylene foil. By way of example, a polyimide foil is used for the substrate foil 4. A thickness of the mold foil 4 is, for example, 25 μm to 100 μm. A thickness of the substrate foil 4 is, for example, 25 μm to 100 μm. A thickness of the carrier foil 3 is, for example, 100 μm to 200 μm.

A conversion means/converter in the form of conversion means/converter particles can be admixed with the silicone base composition 20, preferably in a homogeneously distributed manner, not depicted in the drawings. The conversion means particles comprise, for example, a rare-earth-doped garnet such as YAG:Ce, a rare-earth-doped orthosilicate such as (Ba, Sr)₂SiO₄:Eu or a rare-earth-doped silicon oxynitride or silicon nitride such as (Ba, Sr)₂Si₅N₈:Eu. An average diameter of the conversion means particles is, for example, 2 μm to 20 μm, in particular 3 μm to 15 μm. A proportion by weight of the conversion means/converter particles in the entire silicone foil 2 shaped from the silicone base composition 20 is, in particular, 5 percent by weight to 80 percent by weight, preferably 10 percent by weight to 25 percent by weight or 60 percent by weight to 80 percent by weight.

Optionally, further, preferably particulate substances, for example, of increasing the thermal conductivity of the silicone foil 2 or as diffuser particles, can be admixed with the silicone base composition 20, preferably with a proportion by weight of 0 percent by weight to 50 percent by weight. Such particles comprise or consist, in particular, of oxides or metal fluorides such as aluminum oxide, silicon oxide or calcium fluoride. Average diameters of the particles are preferably 2 μm to 20 μm.

By way of example, no thixotropic agents are admixed with the silicone base composition 20 and the silicone foil 2. In particular, the silicone foil 2 and/or the silicone base composition 20 are/is free or substantially free of silicon dioxide nanoparticles having average diameters of 1 nm to 100 nm or 1 nm to 300 nm. The silicone foil 2 comprises, in particular, no so-called “Aerosil.” It is possible to dispense with a thixotropic agent in particular by virtue of the fact that the silicone base composition 20 has a high viscosity and, consequently, the conversion means particles do not sediment or do not significantly sediment.

As an alternative thereto, it is likewise possible for at least one thixotropic agent, in particular in the form of nanoparticles, for example, based on silicon dioxide to be admixed with the silicone base composition 20 and/or the silicone foil 2.

FIG. 1B shows the mold 5a, 5b, 5c in the closed state. When the mold 5a, 5b, 5c is closed, the part 5a presses onto the parts 5c, which yield as a result, whereby the cavity 50 closes. Closing the mold 5a, 5b, 5c can be effected under vacuum. It is likewise possible for the mold 5a, 5b, 5c to have air outlets (not depicted in the drawings).

When the mold 5a, 5b, 5c is closed, the mold foil 1 and the substrate foil 4 are pressed directly onto one another, whereby the cavity 50 is sealed. The silicone base composition 20 forming the silicone foil 2 is situated substantially between the carrier foil 3 and the mold foil 1 and is in direct contact with them. In a ring-shaped overlap region 24 laterally alongside the carrier foil 3, the silicone base composition 20 is in direct contact with the substrate foil 4. A width of the overlap region 24 is, for example, 0.5 mm to 10 mm, in particular 1 mm to 3 mm, for example, approximately 2 mm. A lateral extent of the cavity 50 is, for example, 50 mm to 500 mm, in particular 60 mm to 200 mm, for example, approximately 100 mm.

In the closed state of the mold 5a, 5b, 5c the shaped silicone foil 2 is, for example, thermally or photochemically precured or completely cured. In the case of photochemical curing, ultraviolet radiation can be radiated, for example, through the part 5a of the mold and through the substrate foil 4 and through the carrier foil 3 into the silicone foil 2.

The silicone foil 2 removed from the mold 5a, 5b, 5c can be seen in FIG. 1C. The mold foil 1 has already been removed from the silicone foil 2. This is made possible by the fact that the silicone foil 2 has a stronger adhesion to the substrate foil 4 than to the mold foil 1. A separating tool 8 is used to remove at least the overlap region 24 from the part of the silicone foil 2 on the carrier foil 3. The silicone foil 2 then no longer projects beyond the carrier foil 3 in a lateral direction, cf. FIG. 1D. In contrast to the illustration in FIG. 1D, the substrate foil 4 can likewise be removed from the carrier foil 3 and/or a further carrier foil (not depicted) can be applied to the silicone foil 2 such that the silicone foil 2 is then situated between the two carrier foils adhering weakly to the silicone foil 2, for example, composed of the same material.

In the optional step in accordance with FIG. 1E, the silicone foil 2 is singulated to form individual silicone laminae 26, for example, by stamping, cutting, water jet cutting or with a laser. In contrast to the illustration in accordance with FIG. 1E, it is likewise possible for the carrier foil 3 also to be affected by singulation. As a further alternative to the illustration in accordance with FIG. 1E, the silicone foil 2 can be applied to a further intermediate carrier (not illustrated) before, with or after singulation. A size of the silicone laminae 26, as seen in plan view is, for example, 0.25 mm² to 4 mm², in particular 1 mm² to 2 mm².

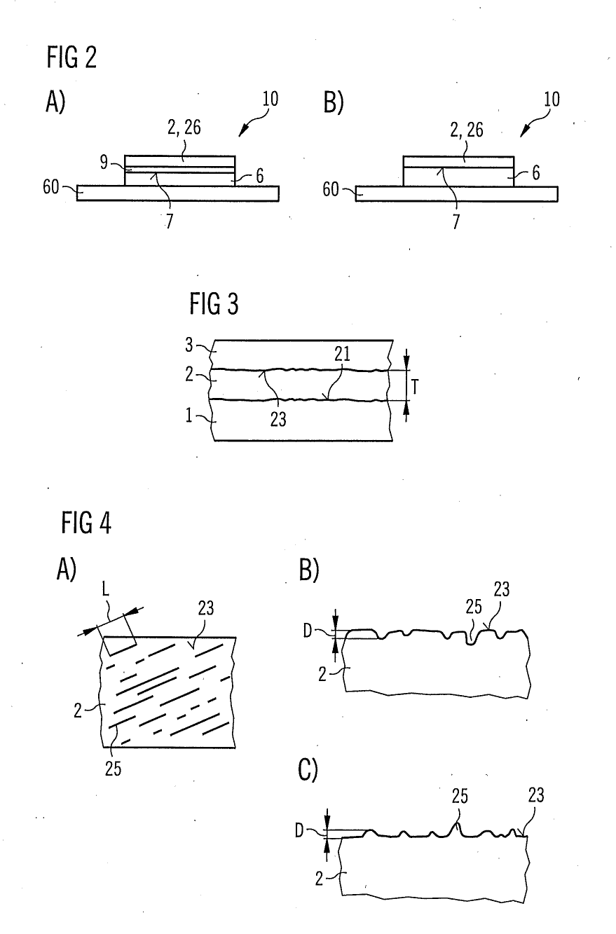

FIG. 2A illustrates an example of an optoelectronic semiconductor component 10. An optoelectronic semiconductor chip 6, for example, a light-emitting diode that emits in the blue spectral range, is applied on a carrier element 60. The silicone lamina 26 composed of the silicone foil 2 is fitted at the radiation main side 7 of the semiconductor chip 6 by a layer of a connecting means 9.

In the further example of the semiconductor component 10 in accordance with FIG. 2B, the silicone lamina 26 composed of the silicone foil 2 is situated directly at the radiation main side 7 of the semiconductor chip 6. The silicone lamina is first applied on the radiation main side 7, for example, with the aid of the carrier foil 3 and is subsequently completely cured, in particular thermally. By applying the silicone laminae 26 to the radiation main side 7 in the not completely cured state, it is possible to realize a good adhesion between the silicone lamina 26 and the semiconductor chip 6 after curing.

FIG. 3 illustrates a further example of the silicone foil 2 in a sectional illustration. As also in all the other examples, the silicone foil 2 has two mutually opposite main sides 21, 23 in direct contact with the mold foil 1 and with the carrier foil 3 during production. A surface structure of the carrier foil 3 and the mold foil 1 is reproduced in the main sides 21, 23 of the silicone foil 2. An average thickness T of the silicone foil 2 is preferably 20 μm to 200 μm or 50 μm to 150 μm. A hardness of the completely cured silicone foil 2 is, as also in all the other examples, in particular Shore A30 to Shore A90.

FIG. 4A illustrates a schematic plan view of the main side 23 of the silicone foil 2 and FIG. 4B illustrates a schematic sectional illustration through the silicone foil 2. A roughening 25 formed at least in the main side 23 by virtue of the carrier foil 3 during production has grooved structures. The individual grooves are oriented substantially parallel to one another and extend substantially along a common main extension direction. Grooves means that a longitudinal extent of the structures encompassed by the roughening 25 is greater than an average width of the individual structures. An average groove length L is, in particular, at least 50 μm. At least some of the grooves can run in an uninterrupted manner between two edges of the main side 23 and extend, in particular in the case of the silicone laminae 26, continuously between two edges of the silicone laminae 26. In contrast to the depiction in FIG. 4A, the average groove length L can then be greater than or equal to an average lateral extent of the main side 23. An average roughness depth D or an average depth of the individual grooves is, in particular, 0.05 μm to 15 μm. Coupling of radiation out of the silicone foil 2 can be improved by the roughening 25. It is likewise possible for an adhesion to a semiconductor chip 6, directly or via the connector 9, to be improved by the roughening 25, cf. FIGS. 2A and 2B.

The term “grooved roughening” preferably includes the fact that the roughening 25 is configured as the negative of a surface, provided with grooves, of the carrier foil 3, for instance. In other words that the structures of the roughening 25 are formed as elongated, wall-like elevations, as illustrated schematically in a sectional illustration in FIG. 4C.

The methods and components described here are not restricted by the description on the basis of the examples. Rather, this disclosure encompasses any novel feature and also any combination of features, which in particular includes any combination of features in the appended claims, even if the feature or combination itself is not explicitly specified in the claims or examples.

1. A method of producing a silicone foil for use in an optoelectronic semiconductor component by molding comprising:
introducing a mold foil into a mold,
introducing a carrier foil into the mold, wherein the carrier foil is fitted on a substrate foil and the substrate foil projects laterally beyond the carrier foil at least in places within a cavity of the mold,
providing and applying a silicone base composition to the mold foil or to the carrier foil,
molding the silicone base composition for the silicone foil in the mold between the mold foil and the carrier foil, wherein the silicone base composition is brought into contact with the substrate foil in at least one overlap region laterally alongside the carrier foil.
removing the mold foil from the silicone foil, and
separating the overlap region.

2. The method according to claim 1, wherein the silicone base composition and/or the silicone foil adhere(s) more strongly to the substrate foil than to the mold foil, and more strongly to the mold foil than to the carrier foil.

3. The method according to claim 1, wherein a surface structure of the mold foil and/or of the carrier foil is reproduced at the silicone foil during molding.

4. The method according to claim 1, wherein the silicone foil is precured with the mold closed and complete curing of the silicone foil is effected only after the mold has been opened.

5. The method according to claim 1, wherein conversion particles are admixed with the silicone base composition in a substantially homogeneously distributed manner prior to application to the carrier foil or to the mold foil, wherein the conversion particles at least partly absorb electromagnetic radiation in a first wavelength range and convert the electromagnetic radiation into a radiation in a second wavelength range different from the first wavelength range.

6. The method according to claim 1, wherein viscosity of the silicone base composition during application to the carrier foil or to the mold foil is at least 0.1 Pa·s.

7. The method according to claim 1, wherein the silicone base composition is free of a thixotropic agent.

8. The method according to claim 1, wherein the mold foil and the carrier foil comprise polyfluorolefin foils, a degree of fluorination of the carrier foil is greater than in the mold foil, and the substrate foil comprises a polyimide foil.

9. The method according to claim 1, wherein a thickness across the silicone foil in the mold fluctuates by at most 15% around an average thickness of the silicone foil.

10. The method according to claim 1, wherein the silicone foil is singulated to form a multiplicity of silicone laminae.

11. A silicone foil comprising;
a matrix material comprising a silicone,
conversion particles distributed substantially homogeneously in the matrix material,
two mutually opposite main sides, and
a grooved roughening formed at at least one of the main sides, wherein an average thickness of the silicone foil is 20 μm to 250 μm.

12. The silicone foil according to claim 11, wherein the roughening has an average roughness depth of 0.05 μm to 15 μm and an average groove length of at least 50 μm.

13. The silicone foil comprising:
a matrix material comprising a silicone,
conversion particles distributed substantially homogeneously in the matrix material,
two mutually opposite main sides, and
a grooved roughening formed at at least one of the main sides, wherein an average thickness of the silicone foil is 20 μm to 250 μm, produced by the method according to claim 1.

14. An optoelectronic semiconductor component Comprising:
at least one optoelectronic semiconductor chip, and
at least one silicone lamina composed of the silicone foil according to claim 11,
wherein the silicone lamina is fitted at least indirectly at a radiation main side of the semiconductor chip and at least partly covers the radiation main side.

15. The method according to claim 1, further comprising removing the substrate foil from the carrier foil.

16. The method according to claim 7, wherein the silicone base composition is substantially free of silicon dioxide nanoparticles having average diameters of 1 nm to 100 nm.
